(19) United States
(12) Patent Application Publication
(10) Pub. No.: US 2025/0380392 A1
(43) Pub. Date: Dec. 11, 2025

(54) ELECTRONIC APPARATUS

(71) Applicant: DENSO TEN Limited, Kobe (JP)

(72) Inventor: Noboru HIDAKA, Kobe (JP)

(73) Assignee: DENSO TEN Limited, Kobe (JP)

(21) Appl. No.: 19/182,982

(22) Filed: Apr. 18, 2025

(30) Foreign Application Priority Data
Jun. 7, 2024 (JP) 2024-092923

(51) Int. Cl. H05K 9/00; H05K 5/00; H05K 5/04

(52) U.S. Cl. CPC H05K 9/0049; H05K 5/006; H05K 5/04

(57) ABSTRACT

An electronic apparatus includes: a circuit board on which an electronic component is mounted; and a housing made of metal inside which the circuit board is disposed. The housing has an internal wall on which the circuit board is mounted and surrounding the electronic component, and at least one projection being provided on a surface of the internal wall that faces the circuit board and being in metal-to-metal contact with the circuit board.

### BACKGROUND OF THE INVENTION

### Field of the Invention

The invention relates to an electronic apparatus including a circuit board on which an electronic component is mounted.

### Description of the Background Art

Conventionally, in an electronic device, there has been proposed a technology that reduces an influence of an electromagnetic wave on a circuit component (for example, refer to the Japanese Published Unexamined Patent Application No. 2008-79200 (Patent document 1)). The Patent Document 1 discloses that, by providing an antenna element so as to be separated from a circuit board, it is possible to reduce an influence of noise on the circuit components due to radio wave radiation from the antenna element. In the Patent document 1, the antenna element is disposed on an internal bottom surface of a housing. Since the circuit board is fixed to a rib adhered on the internal bottom surface of the housing, the circuit board is disposed so as to be separated from the antenna element in a direction orthogonal to the circuit board.

In another method other than a configuration of the Patent document 1, it is possible to shield an electromagnetic wave noise using metal-to-metal contact between a circuit board and a housing within which the circuit board is disposed. In such a configuration, for example, a configuration of an arrangement of leaf springs and a configuration of screw fixation are considered in order to surely obtain the metal-to-metal contact between the circuit board and the housing at a target position.

However, if the leaf springs and screws are arranged one by one at the target position at which the metal-to-metal contact between the circuit board and the housing is obtained, there is a concern that the amount of the leaf springs or screws used increases so that the manufacturing cost of the electronic apparatus increases. Furthermore, the configuration using the leaf springs or screws requires a wide area for arranging these materials, which may result in an increased dead space that occurs in the circuit board. If the dead space increases, the arrangement efficiency of the electronic components in the circuit board may deteriorate.

### SUMMARY OF THE INVENTION

According to one aspect of the invention, an electronic apparatus includes: a circuit board on which an electronic component is mounted; and a housing made of metal inside which the circuit board is disposed, the housing having: an internal wall on which the circuit board is mounted and surrounding the electronic component; and at least one projection being provided on a surface of the internal wall that faces the circuit board and being in metal-to-metal contact with the circuit board.

It is an object of the invention to provide a technology that appropriately shields an electromagnetic wave noise using metal-to-metal contact between a circuit board and a housing.

These and other objects, features, aspects and advantages of the invention will become more apparent from the following detailed description of the invention when taken in conjunction with the accompanying drawings.

### BRIEF DESCRIPTION OF THE DRAWINGS

FIG. 1 is a perspective view illustrating a schematic configuration of an electronic apparatus;

FIG. 2 is an exploded perspective view of the electronic apparatus shown in FIG. 1;

FIG. 3 is a perspective view illustrating a schematic configuration of a housing included in the electronic apparatus;

FIG. 4 is a plan view illustrating the schematic configuration of the housing included in the electronic apparatus;

FIG. 5 is a schematic cross-sectional view of the electronic apparatus along the line V-V in FIG. 1;

FIG. 6 is a schematic cross-sectional view of the electronic apparatus along the line VI-VI in FIG. 1;

FIG. 7 is a schematic cross-sectional view of the electronic apparatus along the line VII-VII in FIG. 1;

FIG. 8 is a schematic cross-sectional view illustrating a pin mark formed on a partition wall illustrated as a comparative example of a first partition wall according to this embodiment; and

FIG. 9 is a cross-sectional view illustrating a schematic configuration of a projection that is provided on an internal wall.

### DESCRIPTION OF THE EMBODIMENTS

Hereinafter, an exemplary embodiment of this invention will be described in detail with reference to the accompanying drawings. The drawings show a XYZ coordinate system as a three-dimensional orthogonal coordinate system appropriately. In the following description, an X-axis direction is a front-rear direction, a Y-axis direction is a left-right direction, and a Z-axis direction is an upper-lower direction. A positive X-axis side is a front side, a negative X-axis side is a rear side, a positive Y-axis side is a right side, a negative Y-axis side is a left side, a positive Z-axis side is an upper side, and a negative Z-axis side is a lower side. However, these directions are simply used for explanation and do not limit an actual positional relationship and direction.

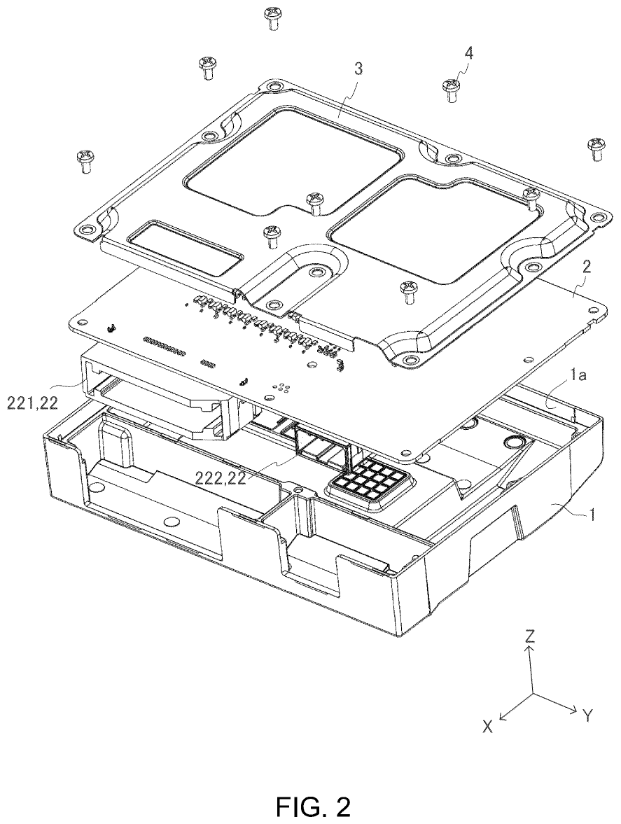

In the XYZ coordinate system, a main surface direction of a circuit board 2 (refer to FIG. 2, etc.) described later is a XY plane direction and a thickness direction of the circuit board 2 is the Z-axis direction. The “main surface” means one surface of front and back surfaces of the circuit board 2 except for side surfaces along the thickness direction of the circuit board 2. The “main surface direction” means a direction parallel to the main surface.

### <1. Outline of Electronic Apparatus>

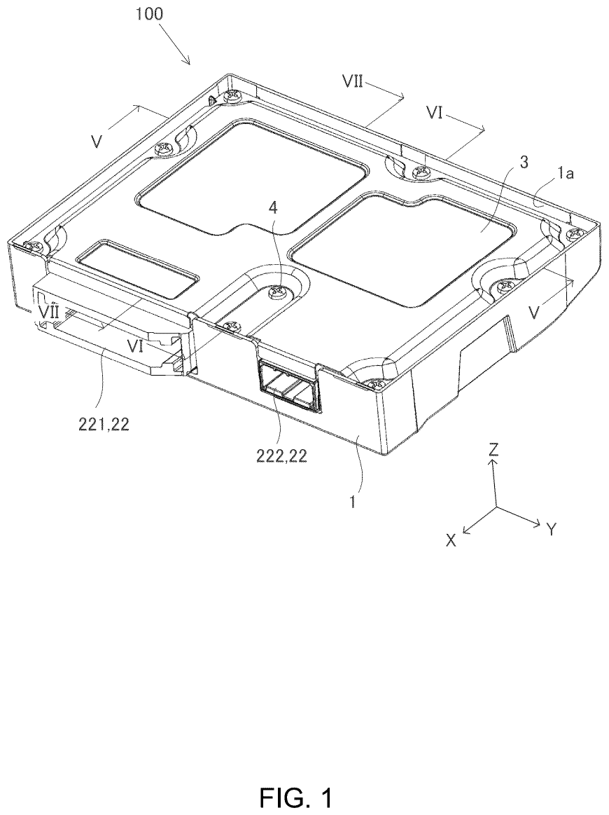

FIG. 1 is a perspective view illustrating a schematic configuration of an electronic apparatus 100 according to this embodiment. FIG. 2 is an exploded perspective view of the electronic apparatus 100 shown in FIG. 1. The electronic apparatus 100 is an ECU (Electronic Control Unit) mounted in a vehicle (not shown). The ECU controls electronic devices mounted in the vehicle. However, the electronic apparatus of this invention is not limited to the ECU, and may be other electronic apparatuses. The electronic apparatus of this invention may be an electronic apparatus to be mounted in something other than the vehicle.

As illustrated in FIG. 1 and FIG. 2, the electronic apparatus 100 includes a housing 1, the circuit board 2, and a cover 3. The housing 1 is a box having an opening 1a on a top surface thereof. The circuit board 2 is disposed inside the housing 1. In other words, the housing 1 houses the circuit board 2. The cover 3 is disposed above the circuit board 2 disposed inside the housing 1, and covers the circuit board 2. The cover 3 is made of metal, and is specifically a pressed material obtained by pressing a sheet metal. The circuit board 2 and the cover 3 that are arranged to overlap each other vertically are fixed to the housing 1 using a plurality of fastening members 4. Specifically, the plurality of fastening members 4 is screws. The circuit board 2 and the cover 3 are jointly fastened to the housing 1 using the plurality of the fastening members 4.

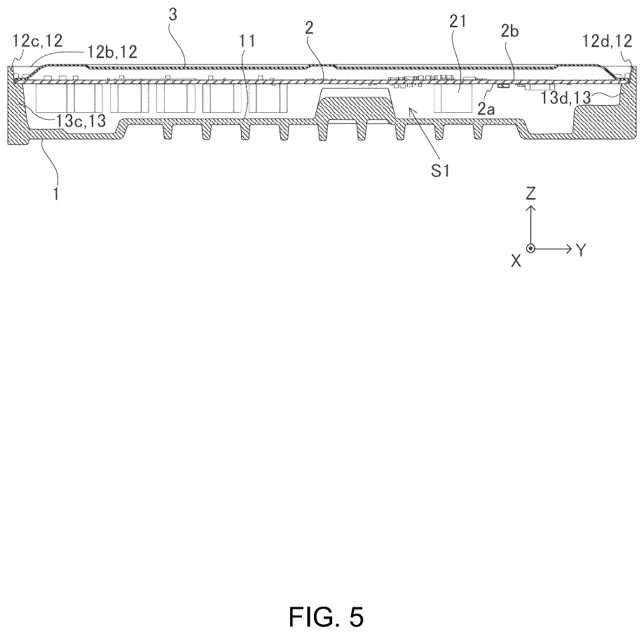

The circuit board 2 is a plate material extending in an XY plane direction. The circuit board 2 is mounted with an electronic component 21 (refer to FIG. 5, etc. described later). Examples of the electronic component 21 include various electronic components including an IC (Integrated Circuit) chip. The circuit board 2 is mounted with a connector 22. That is, the electronic apparatus 100 includes the connector 22 that is mounted on the circuit board 2. The connector 22 is electrically connected to an external device.

Specifically, the connectors 22 include a power supply connector 221 and a signal connector 222. The power supply connector 221 is connected to a power supply line (not shown) that supplies power supply power. The power supply line is, for example, a power supply cable to be electrically connected to a power supply device. Since the power supply connector 221 is provided, the power supply power is supplied to the circuit board 2.

The signal connector 222 is connected to a signal line (not shown) through which a signal is transmitted. Examples of the signal line include a signal transmitter for transmitting a signal that is provided outside the electronic apparatus 100 and a signal cable to be connected to a signal receiver for receiving a signal. The signal transmitter and the signal receiver may be configured as a single apparatus for transmitting and receiving a signal. Since the signal connector 222 is provided, signal input from an outside of the electronic apparatus 100 to the circuit board 2 and signal output from the circuit board 2 to the outside of the electronic apparatus 100 are performed.

### <2. Shielding Structure of Electromagnetic Wave Noise>

Next, a shielding structure of an electromagnetic wave noise in the electronic apparatus 100 configured described above will be described.

### [2-1. Outline]

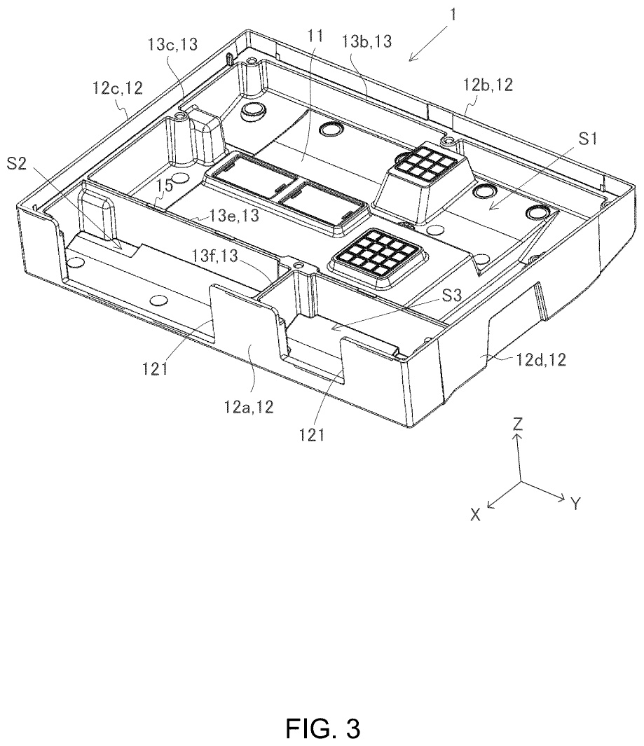

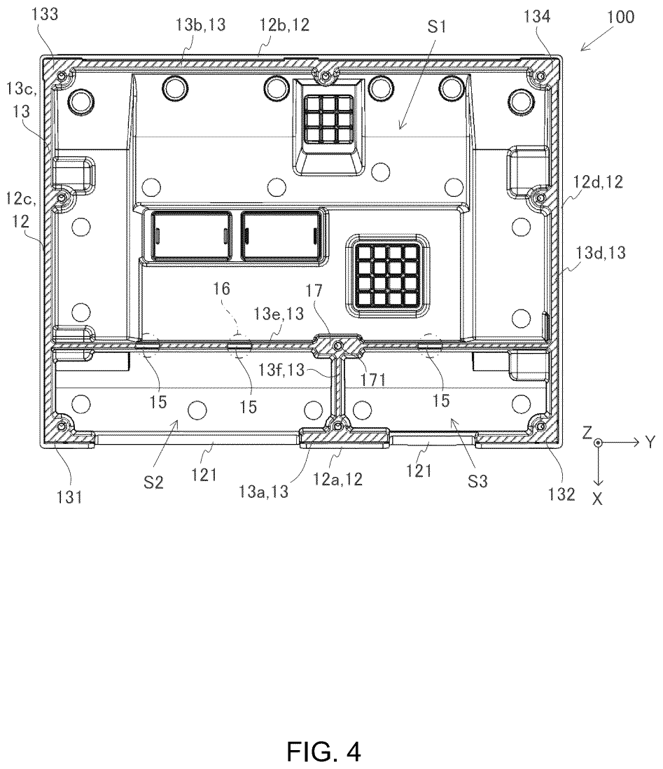

FIG. 3 is a perspective view illustrating a schematic configuration of the housing 1 included in the electronic apparatus 100. FIG. 4 is a plan view illustrating the schematic configuration of the housing 1 included in the electronic apparatus 100. The housing 1 is med of metal. The housing 1 is a molded part. Specifically, the housing 1 a die-cast molded article. More specifically, the housing 1 is an aluminum die-cast molded article configured using aluminum alloy.

As illustrated in FIG. 3 and FIG. 4, the housing 1 has a rectangular shape in a plan view. The housing 1 has a rectangular bottom wall 11 and a rectangular outer peripheral wall 12 in the plan view. The outer peripheral wall 12 extends upward from an upper periphery of the bottom wall 11. Specifically, the outer peripheral wall 12 includes a front outer wall 12a, a rear outer wall 12b, a left outer wall 12c, and a right outer wall 12d. The front outer wall 12a extends upward from an upper front end of the bottom wall 11. The rear outer wall 12b extends upward from an upper rear end of the bottom wall 1. The left outer wall 12c extends upward from an upper left end of the bottom wall 11. The right outer wall 12d extends upward from an upper right end of the bottom wall 11.

The front outer wall 12a is provided with two connector openings 121 through which the power supply connector 221 and the signal connector 222 are exposed to the outside of the electronic apparatus 100. The two connector openings 121 are spaced in a row in the left-right direction. Specifically, each of the two connector openings 121 is formed by cutting out a certain rectangular area including an upper edge of the front outer wall 12a in a front view, and the cut-out area (certain area) is changed accordingly according to a size of the connector 22. In this embodiment, since a size of the power supply connector 221 is different from a size of the signal connector 222, sizes of the two connector openings 121 are different.

As illustrated in FIG. 3 and FIG. 4, the housing 1 has an internal wall 13 therein. The circuit board 2 is mounted on the internal wall 13. The internal wall 13 extends upward from an upper surface of the bottom wall 11 in the same way as the outer peripheral wall 12. However, an upper surface of the internal wall 13 is provided at a lower position than (below) an upper surface of the outer peripheral wall 12. In FIG. 4, hatched areas with oblique lines correspond to the upper surface of the internal wall 13. Since the upper surface of the internal wall 13 is provided at the lower position than the upper surface of the outer peripheral wall 12, the circuit board 2 to be mounted on the internal wall 13 is disposed inside the housing 1.

A part of the internal wall 13 is provided to protrude from the outer peripheral wall 12 toward an interior side of the housing 1. The internal wall 13 includes a front internal wall 13a, a rear internal wall 13b, a left internal wall 13c, and a right internal wall 13d. The front internal wall 13a is provided to protrude rearward from the front outer wall 12a. The front internal wall 13a is not provided in a portion in which each of the connector openings 121 of the front outer wall 12a is provided. The rear internal wall 13b is provided to protrude forward from the rear outer wall 12b. The left internal wall 13c is provided to protrude rightward from the left outer wall 12c. The right internal wall 13d is provided to protrude leftward from the right outer wall 12d.

A left end of the front internal wall 13a is connected to a front end of the left internal wall 13c to constitute a first internal wall corner 131. A right end of the front internal wall 13a is connected to a front end of the right internal wall 13d to constitute a second internal wall corner 132. A left end of the rear internal wall 13b is connected to a rear end of the left internal wall 13c to constitute a third internal wall corner 133. A right end of the rear internal wall 13b is connected to a rear end of the right internal wall 13d to constitute a fourth internal wall corner 134.

The internal wall 13 further includes a first partition wall 13e and a second partition wall 13f. The first partition wall 13e and the second partition wall 13f divide a space inside the housing 1 into a plurality of spaces. The first partition wall 13e extends in the left-right direction. The first partition wall 13e connects a position between the front end and rear end of the left internal wall 13c to a position between the front end and rear end of the right internal wall 13d. The second partition wall 13f extends in the front-rear direction. The second partition wall 13f connects a position between the left end and right end of the front internal wall 13a to a position between a left end and right end of the first partition wall 13e.

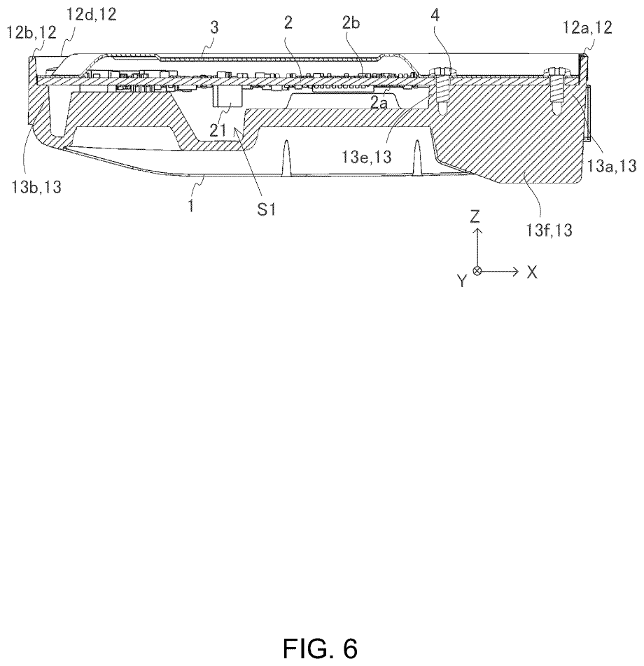

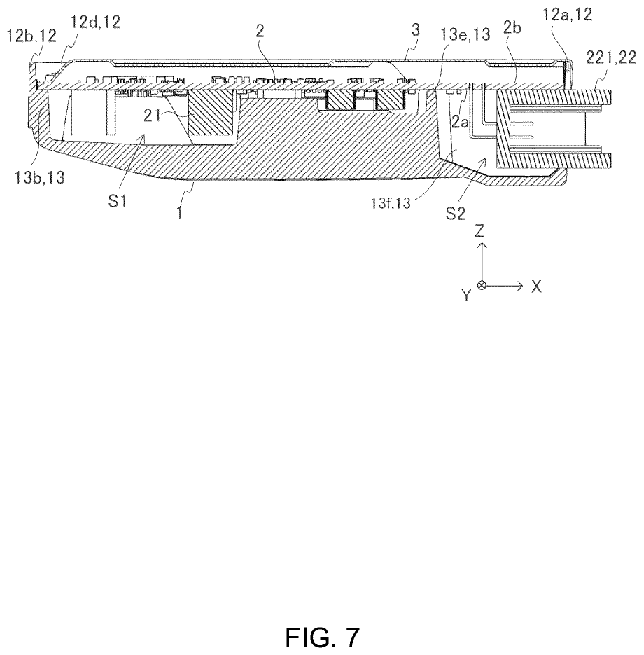

FIG. 5 is a schematic cross-sectional view of the electronic apparatus 100 along the line V-V in FIG. 1. FIG. 6 is a schematic cross-sectional view of the electronic apparatus 100 along the line VI-VI in FIG. 1. FIG. 7 is a schematic cross-sectional view of the electronic apparatus 100 along the line VII-VII in FIG. 1. As illustrated in FIG. 5 to FIG. 7, the circuit board 2 is mounted on the internal wall 13.

Specifically, the upper surfaces of the front internal wall 13a, the rear internal wall 13b, the left internal wall 13c, the right internal wall 13d, the first partition wall 13e, and the second partition wall 13f are located at the same height in the upper-lower direction. The circuit board 2 is mounted on the upper surfaces of the front internal wall 13a, the rear internal wall 13b, the left internal wall 13c, the right internal wall 13d, the first partition wall 13e, and the second partition wall 13f.

At positions of a lower surface of the circuit board 2 facing the upper surfaces of the front internal wall 13a, the rear internal wall 13b, the left internal wall 13c, the right internal wall 13d, the first partition wall 13e, and the second partition wall 13f, grounds (not shown) are provided. Thus, the front internal wall 13a, the rear internal wall 13b, the left internal wall 13c, the right internal wall 13d, the first partition wall 13e, and the second partition wall 13f are in metal-to-metal contact with the circuit board 2. In other words, the internal wall 13 is in metal-to-metal contact with the circuit board 2.

As illustrated in FIG. 3 to FIG. 7, in the electronic apparatus 100, the electronic component 21 mounted on the lower surface of the circuit board 2 is disposed in a space surrounded by the internal wall 13. Specifically, the electronic component 21 is disposed in a first space S1 surrounded by the rear internal wall 13b, the left internal wall 13c, the right internal wall 13d, and the first partition wall 13e.

The power supply connector 221 to be mounted on the lower surface of the circuit board 2 is disposed in a second space S2 surrounded by the front internal wall 13a, the left internal wall 13c, the first partition wall 13e, and the second partition wall 13f. However, the power supply connector 221 is exposed to the outside of the electronic apparatus 100 through one the connector openings 121.

Although detailed illustration is omitted, the signal connector 222 to be mounted on the lower surface of the circuit board 2 is disposed in a third space S3 surrounded by the front internal wall 13a, the right internal wall 13d, the first partition wall 13e, and the second partition wall 13f. However, the signal connector 222 is exposed to the outside of the electronic apparatus 100 through one the connector openings 121.

As illustrated in FIG. 5 to FIG. 7, the circuit board 2 is fixed to the housing 1 using the plurality of the fastening members 4, together with the cover 3 that is disposed on a side of a first surface (upper surface) 2b as an opposite surface of a second surface (lower surface) 2a of the circuit board 2 facing the internal wall 13. Specifically, the circuit board 2 is covered from above by the cover 3 made of metal, and is jointly fastened to the housing 1 with the cover 3 made of metal by the plurality of the fastening members 4 including metal screws. Thus, the circuit board 2 that is disposed inside the housing 1 and covered with the cover 3 is disposed in a space surrounded by metal materials.

As described above, in the electronic apparatus 100 according to this embodiment, the electronic component 21 to be mounted on the circuit board 2 is surrounded by the internal wall 13 included in the housing 1 made of metal. The internal wall 13 is in metal-to-metal contact with the grounds provided on the circuit board 2. Thus, in the configuration according to this embodiment, grounding is strengthened by using the metal-to-metal contact between the circuit board 2 and the housing 1. As a result, it is possible to apply the shielding structure of the electromagnetic wave noise to the electronic component 21 to be mounted on the circuit board 2. That is, in the electronic apparatus 100 according to this embodiment, it is possible to prevent the electronic component 21 from being affected by the electromagnetic wave noise entering from outside and prevent the electromagnetic wave noise from radiating from the electronic component 21 to the outside.

In this embodiment, there is a concern that the electromagnetic wave noise generated from the connectors 22 (particularly, the power supply connector 221) included in the electronic apparatus 100 affects the electronic component 22. However, the internal wall 13 surrounding the electronic component 21 includes the partition wall (first partition wall) 13e separating the connectors 22 from the electronic component 21. In other words, the first space S1 in which the electronic component 21 is disposed, and the second space S2 and the third space S3 in which the connectors 22 are disposed are separated by the first partition wall 13e. In such a configuration, it is possible to prevent the electromagnetic wave noise generated from the connectors 22 from affecting the electronic component 21.

### [2-2. Details]

As described above, the housing 1 is a die-cast molded article. Thus, the housing 1 is manufactured by the steps of: press-fitting metal (in this example, aluminum alloy) melted at a high temperature into a mold; and after press-fitting of molten metal into the mold, releasing a solid molded article from the mold. In the releasing step, by extruding the molded article (housing 1) using an extrusion pin (not shown), the molded article is removed from the mold. When it is assumed that the housing 1 as the molded article is disposed in the mold in an orientation shown in FIG. 4, the housing 1 is extruded by the extrusion pin in a negative Z direction (in a depth direction of this page). The extrusion pin is, for example, columnar, and a plurality of extraction pins is usually used in the releasing step.

As in this embodiment, when the housing 1 has a thin and long-extended partition wall (particularly, the first partition wall 13e) therein, the partition wall tends to deform when the housing 1 is removed from the mold. Considering this point, in the releasing step, the molded article (housing 1) is removed so that the first partition wall 13e is extruded by some extrusion pins among a plurality of extrusion pins extruding the molded article (housing 1). In such a configuration, it is possible to prevent the first partition wall 13e from deforming.

In this embodiment, in the plurality of the extrusion pins, the extrusion pins extruding parts of the housing 1 other than the first partition wall 13e extrude parts of the housing 1 other than the internal walls 13. However, the extraction pins extruding the parts of housing 1 other than the first partition wall 13e may be used for extruding the internal walls 13 except for the first partition wall 13e, such as the second partition wall 13f. In this embodiment, there is a plurality of the extrusion pins to be used for extruding the first partition wall 13e.

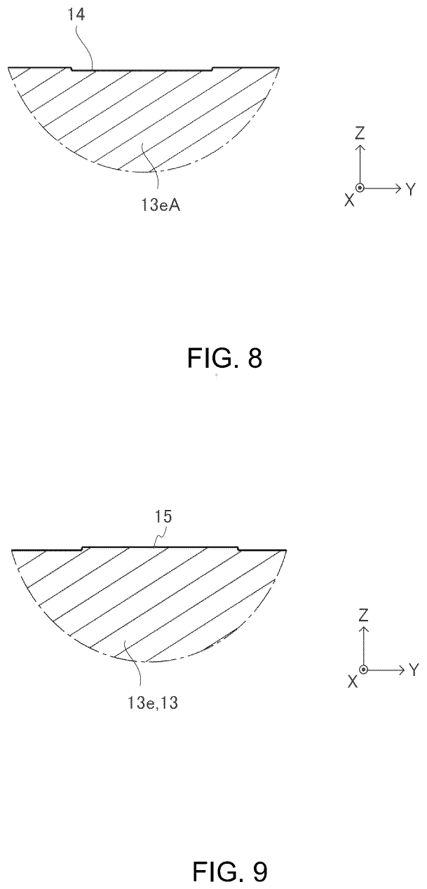

By the way, when extrusion is performed by the plurality of the extrusion pins in the releasing step, there are usually pin marks left on the housing 1 that are formed by extrusion using the plurality of the extrusion pins. FIG. 8 is a schematic cross-sectional view illustrating a pin mark 14 formed on the partition wall 13eA illustrated as a comparative example of the first partition wall 13e according to this embodiment. As illustrated in FIG. 8, the pin mark 14 often has a recessed shape.

In this embodiment, as described above, in order to prevent the electromagnetic wave noise from affecting the electronic component 21, the metal-to-metal contact between the internal wall 13 and the circuit board 2 is caused. If the pin mark 14 having a recessed shape shown in FIG. 8 is formed on an upper surface of the first partition wall 13e, the metal-to-metal contact between the first partition wall 13e and the circuit board 2 may become insufficient. As a result, for example, the electromagnetic wave noise generated in the power supply connector 221 enters the first space S1 in which the electronic component 21 is disposed, which may affect the electronic component 21.

Considering this point, in this embodiment, as illustrated in FIG. 9, the housing 1 has a projection 15 that is provided on the surface (upper surface) of the internal wall 13 facing the circuit board 2 and is in metal-to-metal contact with the circuit board 2. FIG. 9 is a cross-sectional view illustrating a schematic configuration of the projection 15 that is provided on the internal wall 13. Specifically, the projection 15 is in metal-to-metal contact with the grounds provided on the circuit board 2. The projection 15 preferably slightly protrudes with respect to the upper surface on the internal wall 13.

In this way, when the projection 15 is provided on the upper surface of the internal wall 13, it is possible to facilitate the metal-to-metal contact between the internal wall 13 and the circuit board 2 that is mounted on the internal wall 13 at a target position using the projection 15. Even in such a configuration, as in the case where the pin mark 14 having a recessed shape is formed, the metal-to-metal contact between the internal wall 13 and the circuit board 2 may become insufficient. However, it is difficult to ensure a surface parallel to the main surface of the circuit board 2 over a wide area of the upper surface of the internal wall 13. Thus, as in this embodiment, by providing the projection 15, it is preferable to surely obtain the metal-to-metal contact at the target position. When the metal-to-metal contact is obtained at the target position, as described later, other measures for shielding the electromagnetic wave noise are easily executed. Furthermore, when the projection 15 is provided on the upper surface of the internal wall 13, it is possible to reduce, as much as possible, the amount of leaf springs and screws used that are arranged to obtain the metal-to-metal contact between the housing 1 and the circuit board 2 at the target position. Therefore, it is possible to suppress, as much as possible, generation of a dead space due to the arrangement of the leaf springs and screws.

A circle 16 indicated by a dot chain line shown in FIG. 4 indicates a position of an extrusion pin that is pushed against the internal wall 13. As illustrated in FIG. 4, the projection 15 is provided at the position of the extrusion pin that is pushed against the housing 1 when removing the housing 1 from the mold. In such a configuration, the pin mark 14 recessed with respect to the upper surface of the internal wall 13 as described above is suppressed from being formed on the internal wall 13. In such a configuration, a tolerance of a projecting amount of the projection 15 with respect to the upper surface of the internal wall 13 after extrusion by the extrusion pin may be controlled. The tolerance control may be performed, for example, such that the projecting amount should be 0 mm or more and 0.2 mm or less.

In this embodiment, the projection 15 is provided on the first partition wall 13e separating the connectors 22 from the electronic component 21. In such a configuration, it is possible to appropriately apply the shielding structure of the electromagnetic wave noise to a portion of the internal wall 13 that is pushed by the extrusion pin when removing the housing 1 from the mold. According to such a configuration, it is possible to appropriately apply the shielding structure of the electromagnetic wave noise to a portion in which the electromagnetic wave noise is prone to occur due to existence of the power supply connector 221, and the like.

The projection 15 may be provided on parts of the internal wall 13 other than the first partition wall 13e. The projection 15 may not be necessarily provided on the portion of the internal wall 13 that is pushed by the extrusion pin, and may be provided on a portion of the internal wall 13 that is not pushed by the extrusion pin.

As illustrated in FIG. 4, in this embodiment, a plurality of projections 15 is provided at intervals on the internal wall 13 (specifically, the first partition wall 13e). As a result, it is also possible to appropriately apply the shielding structure of the electromagnetic wave noise to a long-extended wall on which there is a plurality of places pushed by the extrusion pins, such as the first partition wall 13e.

As in this embodiment, when the plurality of the projections 15 is provided at intervals on the internal wall 13, each interval between adjacent projections 15 preferably corresponds to a pitch that shields the electromagnetic wave noise at least one place. The pitch that shields the electromagnetic wave noise is determined by a wavelength of the electromagnetic wave noise that should be shielded. The electromagnetic wave noise that should be shielded is appropriately determined by, for example, design of the electronic apparatus 100, and the like.

When the position of the projection 15 is matched with the pitch necessary for shielding the electromagnetic wave noise, the following effect is obtained. When the metal-to-metal contact between the circuit board 2 and the internal wall 13 is caused, even when a gap is generated between the circuit board 2 and the internal wall 13 (in the upper-lower direction) due to existence of the projection 15, it is possible to prevent the electromagnetic wave noise from entering the space (in this embodiment, the first space S1) in which the electronic component 21 is disposed.

The housing 1 preferably has a fixing portion 17 that fixes the circuit board 2 to the internal wall 13 using the plurality of the fastening members 4 between at least one set of adjacent projections 15. As described, in this embodiment, the plurality of the fastening members 4 are screws. Thus, a screw hole 171 is provided in the fixing portion 17 according to this embodiment. The fixing portion 17 is, in other words, a screw fixing portion.

In this way, when the fixing portion 17 is provided, in addition to the projections 15, an area in which the metal-to-metal contact between the internal wall 13 and the circuit board 2 is obtained at the target position is increased. Furthermore, it is possible to prevent floating of the circuit board 2 with respect to the internal wall 13 from being generated between the adjacent projections 15.

In this embodiment, in addition to between the adjacent projections 15, there is provided a plurality of places in which the circuit board 2 is fixed to the internal wall 13 using the plurality of the fastening members 4 while the metal-to-metal contact between the circuit board 2 and the internal wall 13 is caused. For example, such fixing places include places corresponding to four corners of the circuit board 2. The places corresponding to four corners of the circuit board 2 are the first internal wall corner 131 described above, a second internal wall corner 132, a third internal wall corner 133, and a fourth internal wall corner 134 (refer to FIG. 4). Since there is provided a plurality of fixing places using the plurality of the fastening members 4, even when flexure of the circuit board 2 is generated, the metal-to-metal contact between the circuit board 2 and the internal wall 13 is obtained at the target position. At the position at which the projection 15 is provided, the metal-to-metal contact is easily obtained so that fixation by the plurality of the fastening members 4 is unnecessary. Thus, in this embodiment, it is possible to prevent an excess of the fixing portions 17 from being provided.

In this embodiment, as illustrated in FIG. 4, etc., the fixing portion 17 is provided at a place (intersection) at which the first partition wall 13e and the second partition wall 13f are connected to each other. By providing the fixing portion 17 at such a place, it is possible to obtain a strong metal-to-metal contact between the internal wall 13 and the circuit board 2 between two spaces S2 and S3 in which the connectors 22 are disposed. For example, the electromagnetic wave noise generated from the power supply connector 221 is suppressed from entering the space S3 in which the signal connector 222 is disposed. Furthermore, since the fixing portion 17 is provided at the place at which such two walls are connected to each other, the fixing portion 17 is provided at the place with a high rigidity.

### <4. Points of Concern>

The various technological features disclosed in the present specification are able to be modified in various ways without departing from the spirit of the technological creation besides the above embodiments. Features of the above-described preferred embodiments and the modifications thereof may be combined appropriately as long as no conflict arises.

While the invention has been shown and described in detail, the foregoing description is in all aspects illustrative and not restrictive. It is therefore understood that numerous other modifications and variations can be devised without departing from the scope of the invention.

What is claimed is:

1. An electronic apparatus comprising:
a circuit board on which an electronic component is mounted; and
a housing made of metal inside which the circuit board is disposed, the housing having:
an internal wall on which the circuit board is mounted and surrounding the electronic component; and
at least one projection being provided on a surface of the internal wall that faces the circuit board and being in metal-to-metal contact with the circuit board.

2. The electronic apparatus according to claim 1, wherein
the housing is a molded part, and
the at least one projection is provided at a position of an extrusion pin that is pushed against the housing when removing the housing from the mold.

3. The electronic apparatus according to claim 2, wherein
the least one projection includes a plurality of projections, and
the plurality of projections is provided at intervals on the internal wall.

4. The electronic apparatus according to claim 3, wherein
at least one interval between adjacent projections among the plurality of projections corresponds to a pitch that shields an electromagnetic wave noise.

5. The electronic apparatus according to claim 3, wherein
the housing has at least one fixing portion that fixes the circuit board to the internal wall using a fastening member between adjacent projections among the plurality of projections.

6. The electronic apparatus according to claim 5, wherein
the circuit board has a first surface and a second surface that is an opposite surface of the first surface and that faces the internal wall, and
the circuit board is fixed to the housing using a plurality of fastening members, together with a cover that is disposed on a side of the first surface.

7. The electronic apparatus according to claim 1, further comprising
a connector being mounted on the circuit board, wherein
the internal wall includes a partition wall separating the connector from the electronic component, and
the at least one projection is provided on the partition wall.

8. The electronic apparatus according to claim 7, further comprising
a power supply connector being connected to a power supply line that supplies power supply power.
